(19) United States
(12) Patent Application Publication
(10) Pub. No.: US 2025/0338517 A1
(43) Pub. Date: Oct. 30, 2025

(54) VERTICALLY COUPLED INDUCTORS IN SUBSTRATE

(71) Applicant: QUALCOMM Incorporated, San Diego, CA (US)

(72) Inventors: Kai LIU, San Diego, CA (US); Je-Hsiung LAN, San Diego, CA (US); Jonghae KIM, San Diego, CA (US)

(21) Appl. No.: 18/649,636

(22) Filed: Apr. 29, 2024

(51) Int. Cl. H01L 21/768; H01L 23/48; H01L 23/498

(52) U.S. Cl. CPC H10D 1/20; H01L 21/76898; H01L 23/481; H01L 23/49827

(57) ABSTRACT

Disclosed are devices that incorporate vertically coupled inductors in a substrate. The device includes an input inductor and one or more output inductors. Energy from the input inductor is transferred to the output inductors through magnetic coupling. Input and output inductors are formed as three-dimensional loops within a substrate so that there are vertical couplings between the input and the output inductors.

### BACKGROUND OF THE DISCLOSURE

### 1. Field of the Disclosure

This disclosure relates generally to semiconductor devices or packages, and more specifically, but not exclusively, to semiconductor devices/packages that include one or more vertically coupled inductors in a substrate, e.g., for power dividing or splitting and fabrication techniques thereof.

### 2. Description of the Related Art

Integrated circuit (IC) technology has achieved great strides in advancing computing power through miniaturization of active components. In current 5G and WiFi6 radio frequency (RF) frontend packages/packages, RFIC chips such as switches (SW), low noise amplifiers (LNA), power amplifiers (PA), digital amplifiers (DA), filters, etc. are placed side-by-side in a package, e.g., for an RF frontend package. Also, system-on-chip (SoC) dies with multiple cores and processors that perform a wide range of functions are prevalent. For some applications, there is a need for efficient energy transfer between input and output inductors.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a substrate. The semiconductor package may also comprise first and second metal layers, the second metal layer being above the substrate, and the first metal layer being above the second metal layer. The semiconductor package may further comprise third and fourth metal layers, the third metal layer being below the substrate, and the fourth metal layer being below the third metal layer. The semiconductor package may yet comprise a plurality of through-substrate vias (TSV) within the substrate. The semiconductor package may include an input inductor and one or more output inductors.

The input inductor may include one or more input solenoid loops formed from the first metal layer, an input TSV group, and the fourth metal layer. The input TSV group may comprise one or more TSVs of the plurality of TSVs. Each output inductor may include one or more solenoid loops formed from the second metal layer, an output TSV group, and the third metal layer. The output TSV group may comprise one or more TSVs of the plurality of TSVs.

A method of fabricating an exemplary semiconductor package is disclosed. The method may comprise forming a substrate. The method may also comprise forming first and second metal layers, the second metal layer being above the substrate, and the first metal layer being above the second metal layer. The method may further comprise forming third and fourth metal layers, the third metal layer being below the substrate, and the fourth metal layer being below the third metal layer. The method may yet comprise forming a plurality of through-substrate vias (TSV) within the substrate. The semiconductor package may include an input inductor and one or more output inductors. The input inductor may include one or more input solenoid loops formed from the first metal layer, an input TSV group, and the fourth metal layer. The input TSV group may comprise one or more TSVs of the plurality of TSVs. Each output inductor may include one or more solenoid loops formed from the second metal layer, an output TSV group, and the third metal layer. The output TSV group may comprise one or more TSVs of the plurality of TSVs.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates a top view of a conventional semiconductor package.

FIG. 1B illustrates a circuit equivalent of the conventional semiconductor package illustrated in FIG. 1A.

FIGS. 2A and 2B respectively illustrate top and cross-sectional views of a semiconductor package in accordance with one or more aspects of the disclosure.

FIG. 2C illustrates a circuit equivalent of the semiconductor package of FIGS. 2A and 2B in accordance with one or more aspects of the disclosure.

FIG. 3 illustrates a top view of another semiconductor package in accordance with one or more aspects of the disclosure.

FIGS. 4A-4F illustrate examples of stages of fabricating a semiconductor package in accordance with one or more aspects of the disclosure.

FIGS. 5-7 illustrate flow charts of example methods of manufacturing a semiconductor package in accordance with at one or more aspects of the disclosure.

FIG. 8 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, the semiconductor package may comprise a substrate and first, second, third and fourth metal layers. The semiconductor package may also comprise a plurality of through-substrate vias (TSV) within the substrate. The second metal layer may be above the substrate, and the first metal layer may be above the second metal layer. The third metal layer may be below the substrate, and the fourth metal layer may be below the third metal layer. The plurality of TSVs may be within the substrate. The semiconductor package may include an input inductor and one or more output inductors. The input inductor may include one or more input solenoid loops formed from the first metal layer, an input TSV group, and the fourth metal layer. The input TSV group may comprise one or more TSVs of the plurality of TSVs. Each output inductor may include one or more solenoid loops formed from the second metal layer, an output TSV group, and the third metal layer. The output TSV group may comprise one or more TSVs of the plurality of TSVs.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

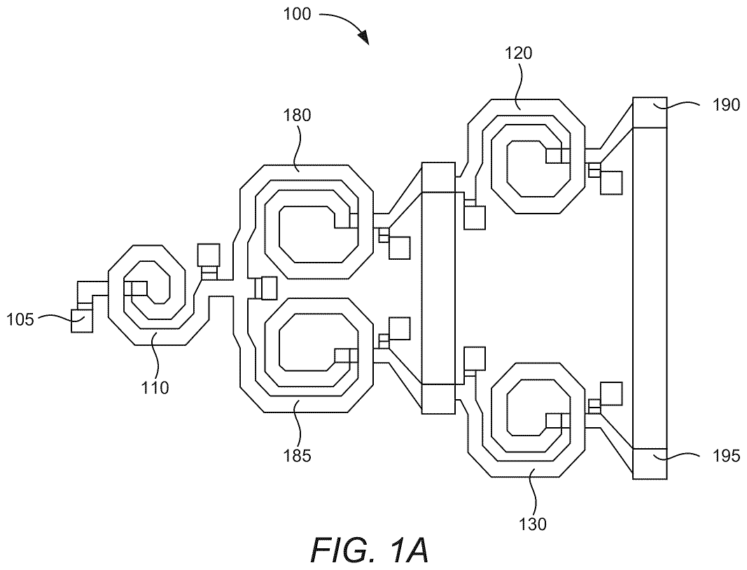

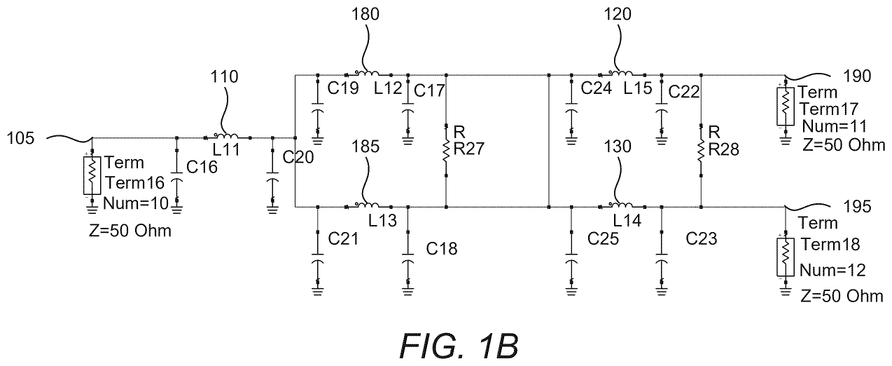

FIG. 1A illustrates a top view of a conventional semiconductor package 100, which in this instance is a 1:2 power divider, which can also be referred to as a power splitter. As seen, the power splitter includes an input inductor 110, and first and second output inductors 120, 130. A first intermediate inductor 180 connects the input inductor 110 with the first output inductor120, and a second intermediate inductor 185 connects the input inductor 110 with the second output inductor 130. Energy provided at an input port 105 are split to first and second output ports 190, 195. FIG. 1B illustrates a circuit equivalent of the conventional semiconductor package illustrated in FIG. 1A. As seen in FIG. 1B, the equivalent circuit, the conventional power splitter also includes various capacitors and resistors for impedance matching.

Note that all of the inductors physically form a single circuit. As such, the semiconductor package 100 splits power based on reactances of the inductors (e.g., the input inductor 110, first and second intermediate inductors 180, 185, and first and second output inductors 120, 130). Also, the semiconductor package 100 is two-dimensional and can take up substantial amount of surface area, e.g., of a substrate.

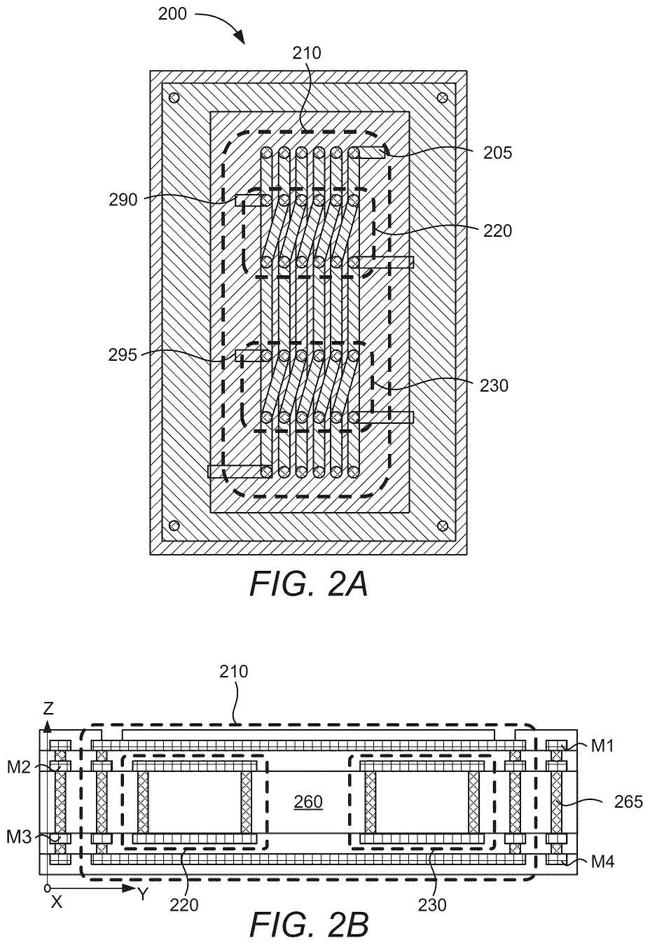

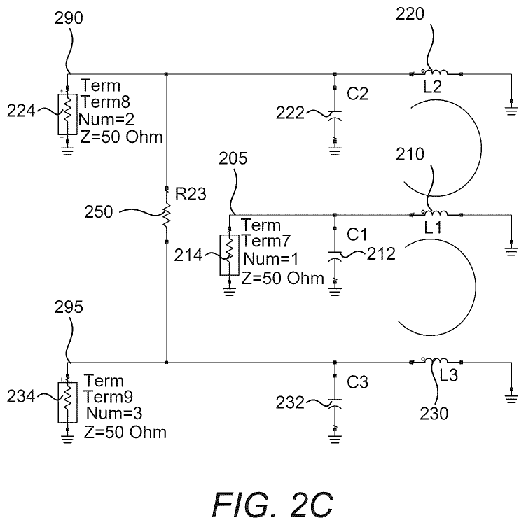

To address such issues associated with power splitters of conventional semiconductor packages, it is proposed to semiconductor packages with input and output inductors that are magnetically coupled vertically, i.e., in three dimensions. FIG. 2A illustrates a top view of a semiconductor package 200 in accordance with one or more aspects of the disclosure. The semiconductor package 200 may include an input inductor 210 connected to an input port 205. The semiconductor package 200 may also include first and second output inductors 220, 230 respectively connected to first and second output ports 290, 295. Energy provided through the input port 205 may be outputted through the first and second output ports 290, 295. All of the inductors 210, 220, 230 may be formed as solenoid loops. The loops of the input inductor 210 are shown as being within a large dashed box, and the loops of the first and second output inductors 220, 230 are shown as being within smaller dashed boxes.

FIG. 2B illustrates a cross-sectional view of the semiconductor package 200 in accordance with one or more aspects of the disclosure. As will be demonstrated with respect to FIG. 2B, solenoid loops of the inductors 210, 220, 230 may be formed from metal layers and through-substrate vias (TSVs). As seen, the semiconductor package 200 may comprise a substrate 260. In an aspect, the substrate 260 may comprise any one or more of a laminate substrate, an embedded trace substrate (ETS), a glass substrate, etc.

The semiconductor package 200 may also include metal layers above and below the substrate 260. In an aspect, the metal layers may be configured as redistribution layers (RDLs). At least two metal layers may be above the substrate 260. For example, first and second metal layers M1, M2 may be formed above the substrate. In particular, the second metal layer M2 may be above the substrate 260, and the first metal layer M1 may be above the second metal layer M2.

Also, at least two metal layers may be below the substrate 260. For example, third and fourth metal layers M3, M4 may be formed below the substrate. In particular, the third metal layer M3 may be below the substrate 260, and the fourth metal layer M4 may be below the third metal layer M3. In this configuration, first and fourth metal layers M1, M4 may be referred to as outer metal layers, and the second and third metal layers may be referred to as inner metal layers.

While four metal layers are shown, this is not a limitation. The number of metal layers can be four (4) or greater. Note that the terms “inner metal layers” and “outer metal layers” are relative. There may be other metal layers that are outside of the “outer metal layers” (e.g., above the first metal layer M1 and/or below the fourth metal layer M4). It is simply noted that between metal layers used to form the solenoid loops, the outer metal layers (e.g., first and fourth metal layers M1, M4) are outside of the inner metal layers (e.g., second and metal layers M2, M3).

A plurality of through-substrate vias (TSV) 265 may be formed within the substrate 260. If the substrate is glass, then TSVs 265 may be referred to as through-glass vias (TGV). If the substrate is a laminate substrate, then TSVs 265 may be referred to as through-laminate vias (TLV).

As seen, in an aspect, the input inductor 210 may be formed from outer metal layers and some of the TSVs. That is, the input inductor 210 may include one or more input solenoid loops formed from the first metal layer M1, an input TSV group, and the fourth metal layer M4. In this aspect, the input TSV group may comprise one or more TSVs 265 of the plurality of TSVs 265.

Also in an aspect, the first output inductor 220 may include one or more first input solenoid loops formed from the second metal layer M2, a first output TSV group, and the third metal layer M3. In this aspect, the first output TSV group may comprise one or more TSVs 265 of the plurality of TSVs 265. The first output TSV group and the input TSV group may have no TSVs 265 in common.

Further in an aspect, the second output inductor 230 may include one or more second input solenoid loops formed from the second metal layer M2, a second output TSV group, and the third metal layer M3. In this aspect, the second output TSV group may comprise one or more TSVs 265 of the plurality of TSVs 265. The second output TSV group and the input TSV group may have no TSVs 265 in common. Also, the first and second TSV groups may have TSVs 265 in common.

FIGS. 2A and 2B illustrate the semiconductor package 200 which includes one input inductor (e.g., input inductor 210) and two output inductors (e.g., first and second output inductors 220, 230). Thus, the semiconductor package 200 may include a 1:2 power splitter. However, this is merely an example. That is, there can be N output inductors, where N≥1. That is, a 1:N power splitting (e.g., 1:2, 1:3, 1:4, etc.) is contemplated. It is noted that if N=1, then the semiconductor package may perform a transformer operation.

Then regarding the output inductors, the following generalities may be made. Each output inductor (e.g., inductors 220, 230) may include one or more solenoid loops formed from the second metal layer M2, an output TSV group, and the third metal layer M3. The output TSV group may comprise one or more TSVs 265 of the plurality of TSVs 265. In an aspect, the input inductor 210 may have no TSV 265 in common with any of the one or more output inductors 220, 230. Also, each output inductor (e.g., first output inductor 220) may have no TSV 265 in common with any other output inductor (e.g., second output inductor 230).

As seen in FIGS. 2A and 2B, it is seen that the solenoid loops of the first and second output inductors 220, 230 are entirely within the solenoid loops of the input inductor 210. Generally, it may be said that for at least one solenoid loop of at least one output inductor (e.g., first and/or second output inductor 220, 230) is within the one or more solenoid loops of the input inductor 210, 310. It should also be noted that the inductances of the output inductors may be independent of each other. For example, the inductance of the first output inductor 220 may be same or different from the inductance of the second output inductor 230.

FIG. 2C illustrates a circuit equivalent of the semiconductor package 200 of FIGS. 2A and 2B in accordance with one or more aspects of the disclosure. In FIG. 2C, the input inductor 210 may be a part of an input circuit, and the first and second output inductors 220, 230 may be parts of an output circuit. Note that the input circuit is separate from the input circuit. To state it another way, the input inductor 210 need not form a circuit with the first output inductor 220 and/or the second output inductor 230. Generally, the input inductor 210 need not form a circuit with any one or more of the output inductors 220, 230.

The coupling between the input inductor 210 and the first and second output inductors 220, 230 may take place magnetically. In an aspect, a vertical magnetic coupling may take place between the input inductor 210 and the magnetic output inductors 220, 230. In an aspect, the vertical magnetic coupling may also be referred to as three-dimensional magnetic coupling.

In FIG. 2C, each of the inductors—the input inductor 210 and the first and second output inductors 220, 230—may be terminated. The input circuit may comprise the input inductor 210 connected with an input capacitor 212. The input capacitor 212 may be used for impedance matching. An input resistor 214 may be in parallel connection with the input capacitor.

The output circuit may comprise the first output inductor 220 connected with a first output capacitor 222. The first output capacitor 222 may be used for impedance matching. A first output resistor 224 may be formed to be connected to the first output port 290.

The output circuit may also comprise the second output inductor 230 connected with a second output capacitor 232. The second output capacitor 232 may be used for impedance matching. A second output resistor 234 may be formed to be connected to the second output port 295.

The output circuit may further comprise a divide resistor 250. A first side of the divide resistor 250 may be electrically coupled to the first output inductor 220. A second side of the divide resistor 250 may be electrically coupled to the second output inductor 230. The divide resistor 250 may be used for isolation between ports 290 and 295.

Any of the resistors and/or capacitors—i.e., any of the first, second and third capacitors 212, 222, 232, and the divide resistor 250—may be surface mounted devices (SMD). It is also contemplated that the resistor and/or capacitors may be implemented as integrated passive devices (IPD). It is of course contemplated that there may be a combination of SMDs and IPDs.

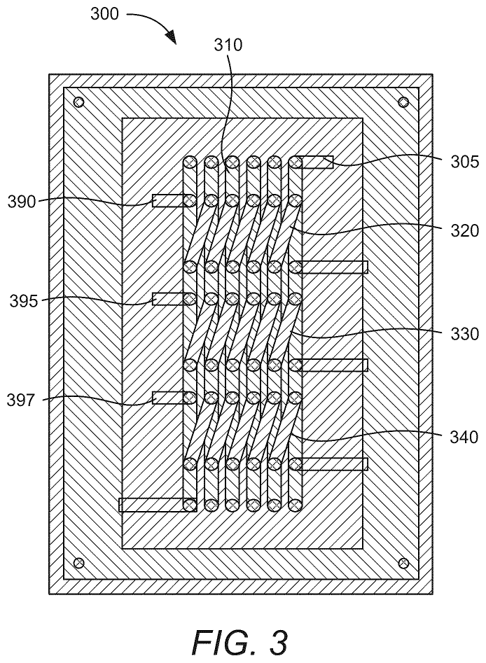

Recall that the number of output inductors can be any number. As a demonstration, FIG. 3 illustrates a top view of another semiconductor package 300 in accordance with one or more aspects of the disclosure. In this instance, the semiconductor package 300 is illustrated as comprising a 1:3 power splitter. As seen, the semiconductor package 300 may include an input inductor 310 connected to an input port 305. The semiconductor package 300 may also include first, second and third output inductors 320, 330, 340 respectively connected to first, second and third output ports 390, 395, 397. Energy provided through the input port 305 may be outputted through the first and second output ports 390, 395, 397. All of the inductors 310, 320, 330, 340 may be formed as solenoid loops. The inductance of each inductor may be same or different from the inductance of any other inductor.

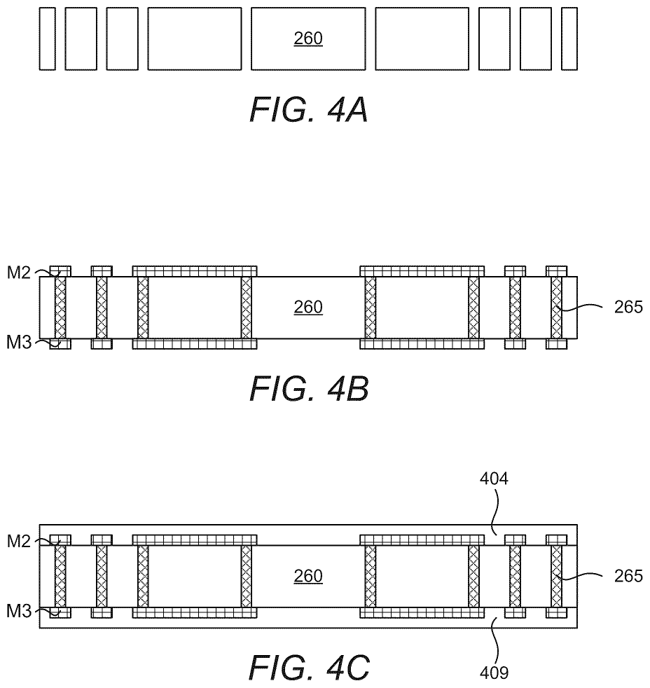

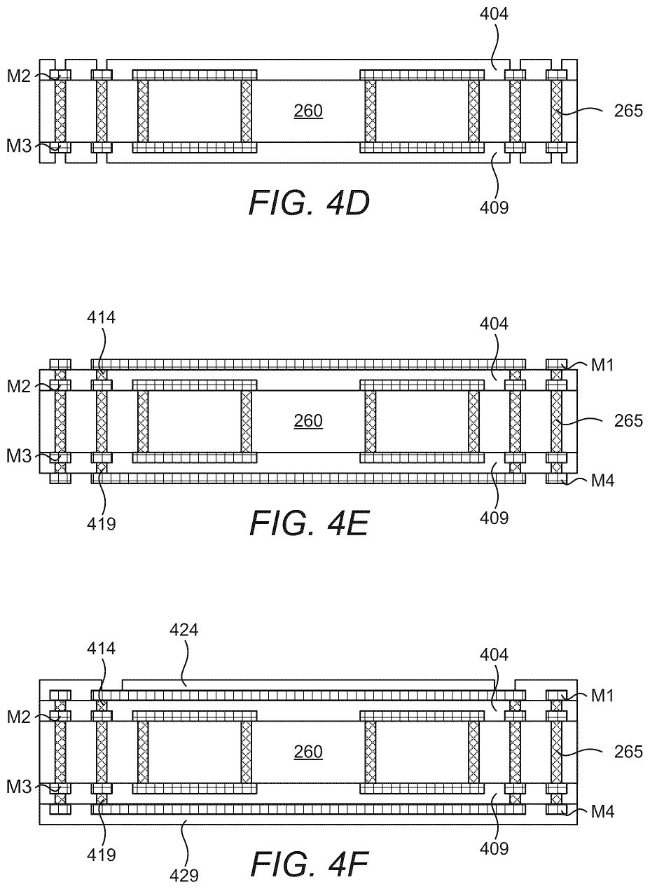

FIGS. 4A-4F illustrate examples of stages of fabricating a semiconductor package—such as the semiconductor package 200, 300—in accordance with at one or more aspects of the disclosure.

FIG. 4A illustrates a stage in which substrate 260 may be provided and holes corresponding to the TSVs 265 may be formed in the substrate 260, e.g., through laser drilling.

FIG. 4B illustrates a stage in which conductive material, such as copper (Cu), tungsten (W), etc., may be deposited to fill the holes of the substrate 260 to thereby form the TSVs 265. The deposited conductive material on upper and lower surfaces of the substrate 260 may be patterned to form the second and third metal layers M2, M3. As a result, one or more output inductors (e.g., output inductors 220, 230, 320, 330, 340) may be formed.

FIG. 4C illustrates a stage in which upper and lower passivation layers 404, 409 may be formed on upper and lower surfaces of the substrate 260, respectively.

FIG. 4D illustrates a stage in which holes may be formed, e.g., through laser drilling, in the upper and lower passivation layers 404, 409 to expose one or more portions of the second and third metal layers M2, M3. The exposed one or more portions of the second and third metal layers M2, M3 may correspond, at least in part, to an output inductor (e.g., output inductor 220, 320).

FIG. 4E illustrates a stage in which another conductive material, such Cu, W, etc., may be deposited to fill the holes of the upper and lower passivation layers 404, 409 to thereby form upper and lower passivation vias (TPV) 414, 419, which are conductive. The deposited conductive material on an upper surface of the upper passivation layer 404 and a lower surface of the lower passivation layer 409 may be patterned to form the first and fourth metal layers M1, M1. As a result, the input inductor (e.g., input inductor 210, 310) may be formed.

FIG. 4F illustrates a stage in which upper and lower solder masks 424, 429 may be formed on the upper and lower passivation layers 404, 409, respectively. The upper and lower solder masks 424, 429 may cover the first and fourth metal layers M1, M4. Thereafter, solder mask openings (SMO) may be formed to expose one or more portions of the first metal layer M1, e.g., for assembling IC die and surface mounted devices (SMDs) (e.g., capacitors, resistors).

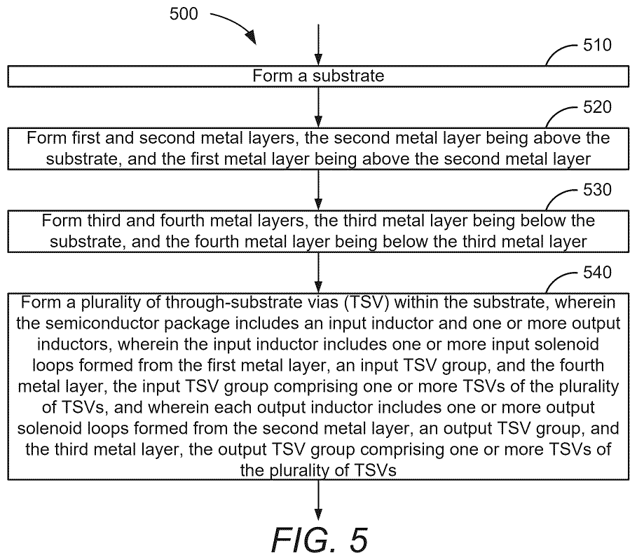

FIG. 5 illustrates a flow chart of an example method 500 of fabricating a semiconductor package, such as the semiconductor package 200, 300 in accordance with at one or more aspects of the disclosure.

In block 510, the substrate 260 may be formed.

In block 520, the first and second metal layers M1, M2 may be formed. The second metal layer M2 may be above the substrate 260, and the first metal layer M1 may be above the second metal layer M2.

In block 530, the third and fourth metal layers M3, M4 may be formed. The third metal layer M3 may be below the substrate 260, and the fourth metal layer M4 may be below the third metal layer M3.

In block 540, a plurality of through-substrate vias (TSV) 265 may be formed within the substrate 260. Recall that the input inductor 210, 310 may include one or more input solenoid loops formed from the first metal layer M1, the input TSV group, and the fourth metal layer M4. Recall also that each output inductor 220, 230, 320, 330, 340 may include one or more output solenoid loops formed from the second metal layer M2, the output TSV group, and the third metal layer M3.

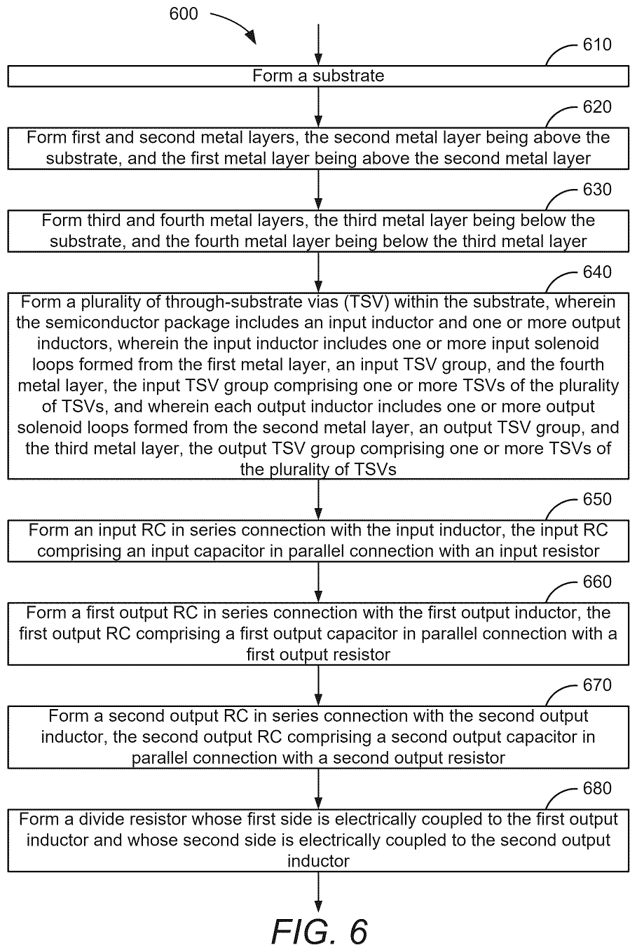

FIG. 6 illustrates a flow chart of an example method 600 of fabricating a semiconductor package, such as the semiconductor package 200, 300 in accordance with at one or more aspects of the disclosure. FIG. 6 may be viewed as being more comprehensive than FIG. 5.

Block 610 may be similar to block 510. That is, in block 610, the substrate 260 may be formed.

Block 620 may be similar to block 520. That is, in block 620, the first and second metal layers M1, M2 may be formed. The second metal layer M2 may be above the substrate 260, and the first metal layer M1 may be above the second metal layer M2.

Block 630 may be similar to block 530. That is, in block 630, the third and fourth metal layers M3, M4 may be formed. The third metal layer M3 may be below the substrate 260, and the fourth metal layer M4 may be below the third metal layer M3.

Block 640 may be similar to block 540. That is, in block 640, a plurality of through-substrate vias (TSV) 265 may be formed within the substrate 260.

In blocks 650-680, it may be assumed that substrate package includes at least first and second outer inductors 220, 230, 320, 330. In block 650, the input RC may be formed to be in series connection with the input inductor 210, 310. Again, the input RC may comprise the input capacitor 212 in parallel connection with the input resistor 214.

In block 660, the first output RC may be formed to be in series connection with the first output inductor 220, 320. The first output RC may comprise the first output capacitor 222 in parallel connection with the first output resistor 224.

In block 670, the second output RC may be formed to be in series connection with the second output inductor 230, 330. The second output RC may comprise the second output capacitor 232 in parallel connection with the second output resistor 234.

In block 680, a divide resistor 250 may be formed. A first side of the divide resistor 250 may be electrically coupled to the first output inductor 220, 320. A second side of the divide resistor 250 may be electrically coupled to the second output inductor 230, 330.

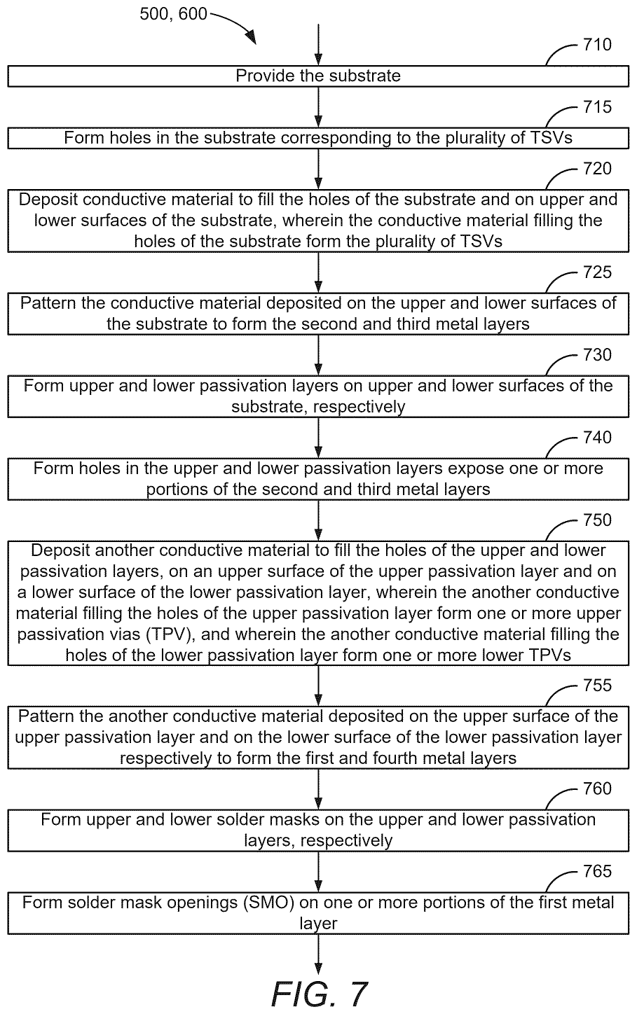

FIG. 7 illustrates a flow chart of an example process to perform the method 500, 600 of fabricating a semiconductor device in accordance with at one or more aspects of the disclosure.

In block 710, the substrate 260 may be provided. Block 710 may correspond to the stage illustrated in FIG. 4A.

In block 715, holes corresponding to the TSVs 265 may be formed in the substrate 260, e.g., through laser drilling. Block 715 may also correspond to the stage illustrated in FIG. 4A.

In block 720, conductive material (e.g., Cu, W, etc.) may be deposited to fill the holes of the substrate 260 and on upper and lower surfaces of the substrate 260. The conductive material filling the holes of the substrate 260 may form the plurality of TSVs 265. Block 720 may correspond to the stage illustrated in FIG. 4B.

In block 725, the conductive material deposited on the upper and lower surfaces of the substrate 260 may be patterned to form the second and third metal layers M2, M3. Recall that the output inductors (e.g., inductors 220, 230, 320, 330, 340, etc.) may be formed as a result. Block 725 may also correspond to the stage illustrated in FIG. 4B.

In block 730, upper and lower passivation layers 404, 409 may be formed on upper and lower surfaces of the substrate 260, respectively. Block 730 may correspond to the stage illustrated in FIG. 4C.

In block 740, holes in the upper and lower passivation layers 404, 409 may be formed expose one or more portions of the second and third metal layers M2, M3. In an aspect, the exposed one or more portions of the second and third metal layers M2, M3 may correspond, at least in part, to an input inductor (e.g., input inductor 210, 310). Block 740 may correspond to the stage illustrated in FIG. 4D.

In block 750, another conductive material (e.g., Cu, W, etc.) may be deposited to fill the holes of the upper and lower passivation layers 404, 409, on an upper surface of the upper passivation layer 404 and on a lower surface of the lower passivation layer 409. The another conductive material filling the holes of the upper passivation layer 404 may form one or more upper passivation vias TPV 414. Also, the another conductive material filling the holes of the lower passivation layer 409 may form one or more lower TPVs 419. Block 750 may correspond to the stage illustrated in FIG. 4E.

In block 755, the another conductive material deposited on the upper surface of the upper passivation layer 404 and on the lower surface of the lower passivation layer 409 may be patterned respectively to form the first and fourth metal layers M1, M4. Block 755 may also correspond to the stage illustrated in FIG. 4E.

In block 760, upper and lower solder masks 424, 429 may be formed on the upper and lower passivation layers 404, 409, respectively. The upper and lower solder masks 424, 429 may cover the first and fourth metal layers M1, M4. Block 760 may correspond to the stage illustrated in FIG. 4F.

In block 765, solder mask openings (SMO) may be formed to expose one or more portions of the first metal layer M1, e.g., for assembling IC die and surface mounted devices (SMDs) (e.g., capacitors, resistors). Block 765 may also correspond to the stage illustrated in FIG. 4F.

The following should be noted regarding the flow indicated in FIGS. 5-7. Unless otherwise indicated, the flow of blocks do not necessarily limit the ordering in which the blocks may be performed. In other words, the blocks may be performed in any order that is logical.

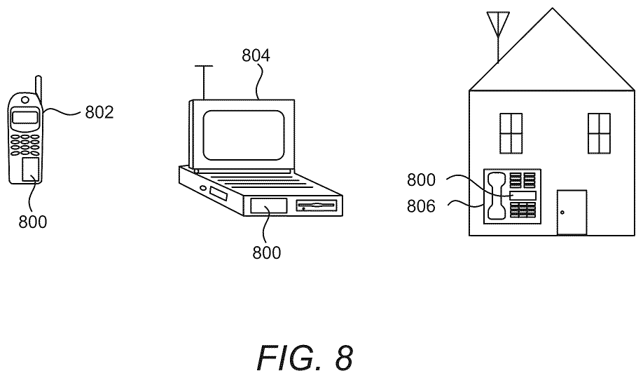

FIG. 8 illustrates various electronic devices 800 that may be integrated with any of the aforementioned semiconductor package in accordance with various aspects of the disclosure. For example, a mobile phone device 802, a laptop computer device 804, and a fixed location terminal device 806 may each be considered generally user equipment (UE) and may include one or more semiconductor packages (e.g., semiconductor package 200, 300) as described herein. The devices 802, 804, 806 illustrated in FIG. 8 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A semiconductor package, comprising: a substrate; first and second metal layers, the second metal layer being above the substrate, and the first metal layer being above the second metal layer; third and fourth metal layers, the third metal layer being below the substrate, and the fourth metal layer being below the third metal layer; and a plurality of through-substrate vias (TSV) within the substrate, wherein the semiconductor package includes an input inductor and one or more output inductors, wherein the input inductor includes one or more input solenoid loops formed from the first metal layer, an input TSV group, and the fourth metal layer, the input TSV group comprising one or more TSVs of the plurality of TSVs, and wherein each output inductor includes one or more solenoid loops formed from the second metal layer, an output TSV group, and the third metal layer, the output TSV group comprising one or more TSVs of the plurality of TSVs.

Clause 2: The semiconductor package of clause 1, wherein the input inductor magnetically couples with at least one output inductor, and wherein the input inductor and the at least one output inductor do not form a circuit.

Clause 3: The semiconductor package of any of clauses 1-2, wherein at least one solenoid loop of at least one output inductor is within the one or more solenoid loops of the input inductor.

Clause 4: The semiconductor package of clause 3, wherein the one or more solenoid loops of each output inductor are within the one or more solenoid loops of the input inductor.

Clause 5: The semiconductor package of any of clauses 1-4, wherein the input inductor has no TSV in common with any of the one or more output inductors.

Clause 6: The semiconductor package of clause 5, wherein each output inductor has no TSV in common with any other output inductor.

Clause 7: The semiconductor package of any of clauses 1-6, wherein the one or output inductors includes at least a first output inductor and a second output inductor.

Clause 8: The semiconductor package of clause 7, wherein an inductance of the first output inductor is different from an inductance of the second output inductor.

Clause 9: The semiconductor package of any of clauses 7-8, further comprising: an input RC in series connection with the input inductor, the input RC comprising an input capacitor in parallel connection with an input resistor; a first output RC in series connection with the first output inductor, the first output RC comprising a first output capacitor in parallel connection with a first output resistor; and a second output RC in series connection with the second output inductor, the second output RC comprising a second output capacitor in parallel connection with a second output resistor.

Clause 10: The semiconductor package of clause 9, further comprising: a divide resistor whose first side is electrically coupled to the first output inductor and whose second side is electrically coupled to the second output inductor.

Clause 11: The semiconductor package of any of clauses 9-10, wherein any one or more of the input capacitor, the first output capacitor, and the second output capacitor are surface mounted devices (SMD).

Clause 12: The semiconductor package of any of clauses 1-11, wherein the substrate is any one or more of a laminate substrate, an embedded trace substrate (ETS), or a glass substrate.

Clause 13: The semiconductor package of any of clauses 1-12, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 14: A method of fabricating a semiconductor package, the method comprising: forming first and second metal layers, the second metal layer being above the substrate, and the first metal layer being above the second metal layer; forming third and fourth metal layers, the third metal layer being below the substrate, and the fourth metal layer being below the third metal layer; and forming a plurality of through-substrate vias (TSV) within the substrate, wherein the semiconductor package includes an input inductor and one or more output inductors, wherein the input inductor includes one or more input solenoid loops formed from the first metal layer, an input TSV group, and the fourth metal layer, the input TSV group comprising one or more TSVs of the plurality of TSVs, and wherein each output inductor includes one or more solenoid loops formed from the second metal layer, an output TSV group, and the third metal layer, the output TSV group comprising one or more TSVs of the plurality of TSVs.

Clause 15: The method of clause 14, wherein the input inductor magnetically couples with at least one output inductor, and wherein the input inductor and the at least one output inductor do not form a circuit.

Clause 16: The method of any of clauses 14-15, wherein at least one solenoid loop of at least one output inductor is within the one or more solenoid loops of the input inductor.

Clause 17: The method of clause 16, wherein the one or more solenoid loops of each output inductor are within the one or more solenoid loops of the input inductor.

Clause 18: The method of any of clauses 14-17, wherein the input inductor has no TSV in common with any of the one or more output inductors.

Clause 19: The method of clause 18, wherein each output inductor has no TSV in common with any other output inductor.

Clause 20: The method of any of clauses 14-19, wherein fabricating the semiconductor package comprises: providing the substrate; forming holes in the substrate corresponding to the plurality of TSVs; depositing conductive material to fill the holes of the substrate and on upper and lower surfaces of the substrate, wherein the conductive material filling the holes of the substrate form the plurality of TSVs; patterning the conductive material deposited on the upper and lower surfaces of the substrate to form the second and third metal layers; forming upper and lower passivation layers on upper and lower surfaces of the substrate, respectively; forming holes in the upper and lower passivation layers expose one or more portions of the second and third metal layers; depositing another conductive material to fill the holes of the upper and lower passivation layers, on an upper surface of the upper passivation layer and on a lower surface of the lower passivation layer, wherein the another conductive material filling the holes of the upper passivation layer form one or more upper passivation vias (TPV), and wherein the another conductive material filling the holes of the lower passivation layer form one or more lower TPVs; and patterning the another conductive material deposited on the upper surface of the upper passivation layer and on the lower surface of the lower passivation layer respectively to form the first and fourth metal layers.

Clause 21: The method of any of clauses 14-20, wherein the one or output inductors includes at least a first output inductor and a second output inductor.

Clause 22: The method of clause 21, wherein an inductance of the first output inductor is different from an inductance of the second output inductor.

Clause 23: The method of any of clauses 21-22, further comprising: forming an input RC in series connection with the input inductor, the input RC comprising an input capacitor in parallel connection with an input resistor; forming a first output RC in series connection with the first output inductor, the first output RC comprising a first output capacitor in parallel connection with a first output resistor; and forming a second output RC in series connection with the second output inductor, the second output RC comprising a second output capacitor in parallel connection with a second output resistor.

Clause 24: The method of clause 23, further comprising: forming a divide resistor whose first side is electrically coupled to the first output inductor and whose second side is electrically coupled to the second output inductor.

Clause 25: The method of any of clauses 23-24, wherein any one or more of the input capacitor, the input resistor, the first output capacitor, the first output resistor, the second output capacitor, and the second output resistor are surface mounted devices (SMD).

Clause 26: The method of any of clauses 14-25, wherein the substrate is any one or more of a laminate substrate, an embedded trace substrate (ETS), or a glass substrate.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a substrate;
first and second metal layers, the second metal layer being above the substrate, and the first metal layer being above the second metal layer;
third and fourth metal layers, the third metal layer being below the substrate, and the fourth metal layer being below the third metal layer; and
a plurality of through-substrate vias (TSV) within the substrate,
wherein the semiconductor package includes an input inductor and one or more output inductors,
wherein the input inductor includes one or more input solenoid loops formed from the first metal layer, an input TSV group, and the fourth metal layer, the input TSV group comprising one or more TSVs of the plurality of TSVs, and
wherein each output inductor includes one or more solenoid loops formed from the second metal layer, an output TSV group, and the third metal layer, the output TSV group comprising one or more TSVs of the plurality of TSVs.

2. The semiconductor package of claim 1,
wherein the input inductor magnetically couples with at least one output inductor, and
wherein the input inductor and the at least one output inductor do not form a circuit.

3. The semiconductor package of claim 1, wherein at least one solenoid loop of at least one output inductor is within the one or more solenoid loops of the input inductor.

4. The semiconductor package of claim 3, wherein the one or more solenoid loops of each output inductor are within the one or more solenoid loops of the input inductor.

5. The semiconductor package of claim 1, wherein the input inductor has no TSV in common with any of the one or more output inductors.

6. The semiconductor package of claim 5, wherein each output inductor has no TSV in common with any other output inductor.

7. The semiconductor package of claim 1, wherein the one or output inductors includes at least a first output inductor and a second output inductor.

8. The semiconductor package of claim 7, wherein an inductance of the first output inductor is different from an inductance of the second output inductor.

9. The semiconductor package of claim 7, further comprising:
an input RC in series connection with the input inductor, the input RC comprising an input capacitor in parallel connection with an input resistor;
a first output RC in series connection with the first output inductor, the first output RC comprising a first output capacitor in parallel connection with a first output resistor; and
a second output RC in series connection with the second output inductor, the second output RC comprising a second output capacitor in parallel connection with a second output resistor.

10. The semiconductor package of claim 9, further comprising:
a divide resistor whose first side is electrically coupled to the first output inductor and whose second side is electrically coupled to the second output inductor.

11. The semiconductor package of claim 9, wherein any one or more of the input capacitor, the first output capacitor, and the second output capacitor are surface mounted devices (SMD).

12. The semiconductor package of claim 1, wherein the substrate is any one or more of a laminate substrate, an embedded trace substrate (ETS), or a glass substrate.

13. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

14. A method of fabricating a semiconductor package, the method comprising:
forming a substrate;
forming first and second metal layers, the second metal layer being above the substrate, and the first metal layer being above the second metal layer;
forming third and fourth metal layers, the third metal layer being below the substrate, and the fourth metal layer being below the third metal layer; and
forming a plurality of through-substrate vias (TSV) within the substrate,
wherein the semiconductor package includes an input inductor and one or more output inductors,
wherein the input inductor includes one or more input solenoid loops formed from the first metal layer, an input TSV group, and the fourth metal layer, the input TSV group comprising one or more TSVs of the plurality of TSVs, and
wherein each output inductor includes one or more solenoid loops formed from the second metal layer, an output TSV group, and the third metal layer, the output TSV group comprising one or more TSVs of the plurality of TSVs.

15. The method of claim 14,
wherein the input inductor magnetically couples with at least one output inductor, and
wherein the input inductor and the at least one output inductor do not form a circuit.

16. The method of claim 14, wherein at least one solenoid loop of at least one output inductor is within the one or more solenoid loops of the input inductor.

17. The method of claim 16, wherein the one or more solenoid loops of each output inductor are within the one or more solenoid loops of the input inductor.

18. The method of claim 14,
wherein the input inductor has no TSV in common with any of the one or more output inductors, or
wherein each output inductor has no TSV in common with any other output inductor, or
both.

19. The method of claim 14,
wherein the one or output inductors includes at least a first output inductor and a second output inductor, and
wherein an inductance of the first output inductor is different from an inductance of the second output inductor.

20. The method of claim 14, wherein fabricating the semiconductor package comprises:
providing the substrate;
forming holes in the substrate corresponding to the plurality of TSVs;
depositing conductive material to fill the holes of the substrate and on upper and lower surfaces of the substrate, wherein the conductive material filling the holes of the substrate form the plurality of TSVs;
patterning the conductive material deposited on the upper and lower surfaces of the substrate to form the second and third metal layers;
forming upper and lower passivation layers on upper and lower surfaces of the substrate, respectively;
forming holes in the upper and lower passivation layers expose one or more portions of the second and third metal layers;
depositing another conductive material to fill the holes of the upper and lower passivation layers, on an upper surface of the upper passivation layer and on a lower surface of the lower passivation layer, wherein the another conductive material filling the holes of the upper passivation layer form one or more upper passivation vias (TPV), and wherein the another conductive material filling the holes of the lower passivation layer form one or more lower TPVs; and
patterning the another conductive material deposited on the upper surface of the upper passivation layer and on the lower surface of the lower passivation layer respectively to form the first and fourth metal layers.
